(19) United States
(12) Patent Application Publication
(10) Pub. No.: US 2021/0066520 A1
(43) Pub. Date: Mar. 4, 2021

(54) Copper Indium Gallium Di-selenide (CIGS) Solar Cell with Staggered Back Contacts (SBC)

(71) Applicant: THE UNITED STATES OF AMERICA, AS REPRESENTED BY THE SECRETARY OF THE NAVY, Arlington, VA (US)

(72) Inventors: Sherif MICHAEL, Pebble Beach, CA (US); Jose Alberto HERRERA, Anaheim, CA (US)

(21) Appl. No.: 16/997,270

(22) Filed: Aug. 19, 2020

Related U.S. Application Data
(60) Provisional application No. 62/893,574, filed on Aug. 29, 2019.

(51) Int. Cl. H01L 31/032; H01L 31/0224; H01L 31/0296

(52) U.S. Cl. CPC H01L 31/0322; H01L 31/0296; H01L 31/022483; H01L 31/022441

(57) ABSTRACT

Embodiments in accordance with the invention provide a solar cell design having a single copper indium gallium di-selenide (CIGS) cell with a staggered back contacts (SBC).

### CROSS-REFERENCE TO RELATED APPLICATIONS

This patent application is a non-provisional of and claims the benefit of U.S. Provisional application 62/893,574, filed Aug. 29, 2019, which is hereby incorporated by reference in its entirety.

### BACKGROUND OF THE INVENTION

### 1. Field of the Invention

One or more embodiments relates to solar cells, and more particularly to copper indium gallium di-selenide (CIGS) solar cells having staggered back contacts (SBC).

### 2. Description of the Related Art

Solar cells which utilize top contacts on copper indium gallium di-selenide (CIGS) are known in the prior art. A prior art top contact CIGS cell 100 is shown in FIG. 1 and is a hetero-structure device, meaning cell 100 has junctions between different bandgap materials. The top of cell 100 has an aluminum (Al) contact 102 which serves as the cathode of cell 100. Just below Al contact 102 is an n-type zinc oxide (ZnO) window layer 104. ZnO has a bandgap (E_{G}) of 3.3 eV and is considered a transparent conducting oxide (TCO). Being transparent and conductive, ZnO collects the carriers that are generated in cell 100 and then sends them up to the cathode, Al contact 102. The large bandgap of ZnO also allows more photons to interact with a CIGS layer 108 lower in cell 100. Just below (ZnO) window layer 104 is an n-type cadmium sulfide (CdS) buffer layer 106. CdS has an E_{G} of 2.3 eV and the purpose of CdS buffer layer 106 is to tunnel photons to CIGS layer 108 underlying CdS buffer layer 106. CdS is also the N side to the PN junction of cell 100, which is necessary to its operation. Directly below CdS buffer layer 106 is a p-type CIGS absorber layer 108. CIGS absorber layer 108 produces the majority of the carriers based on the number of photons that enter cell 100. CIGS absorber layer 108 is composed of two materials, CuInSe2 (CIS) and CuGaSe2 (CGS), both of which are direct bandgap semiconductors. Depending on the ratio of CIS to CGS, the bandgap can shift between 1.07-1.76 eV. As a solar cell typically needs an anode to function, a molybdenum (Mo) layer 110 is utilized due to its compatibility with CIGS to function as an anode in cell 100. Prior art top contact CIGS cell 100 attempts to minimize the shadowing effect by using a small top contact, Al contact 102; however, power is still lost whenever sunlight Q is obstructed from reaching the solar cell 100 by the small top contact, Al contact 102.

### SUMMARY OF THE INVENTION

Embodiments in accordance with the invention provide a solar cell design having a single copper indium gallium di-selenide (CIGS) cell with a staggered back contacts (SBC). Embodiments in accordance with the invention remove the shadowing effect seen with the prior art top contact CIGS cell design and provide increased power output.

Embodiments in accordance with the invention are best understood by reference to the following detailed description when read in conjunction with the accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates a two-dimensional representation of prior art top contact CIGS cell. A single, horizontal section or “slice” of the solar cell is shown. The back region of the cell is periodic and made up of many adjoining sections.

FIG. 2 illustrates a two-dimensional representation of a SBC CIGS cell in accordance with one embodiment of the invention. A single, horizontal section or “slice” of the solar cell is shown. The back region of the cell is periodic and made up of many adjoining sections.

FIG. 3 illustrates a photogeneration rate of a prior art top contact CIGS cell.

FIG. 4 illustrates a photogeneration rate of a SBC CIGS cell in accordance with one embodiment of the invention.

FIG. 5 illustrates a current versus voltage comparison of a prior art top contact CIGS cell and one embodiment of a SBC CIGS cell in accordance with the invention.

FIG. 6 illustrates regions of a SBC CIGS cell in accordance with one embodiment of the invention.

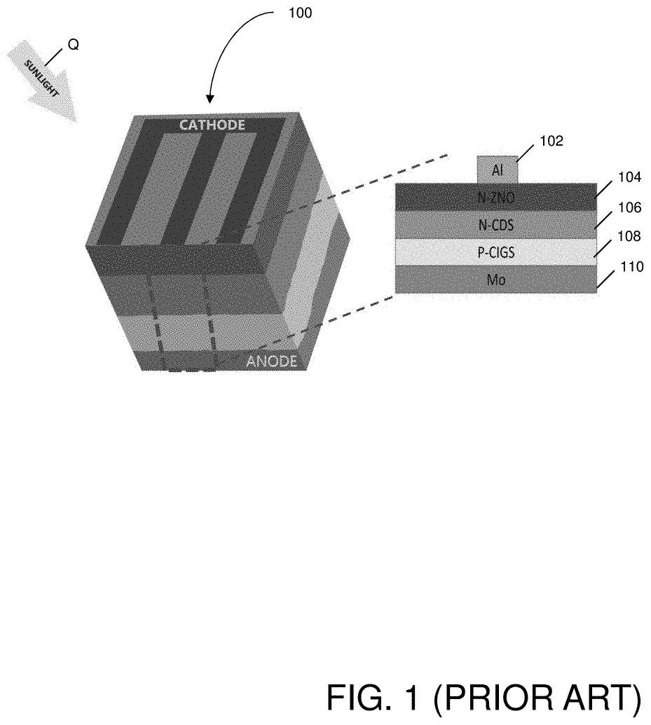

Embodiments in accordance with the invention are further described herein with reference to the drawings.

### DETAILED DESCRIPTION OF THE INVENTION

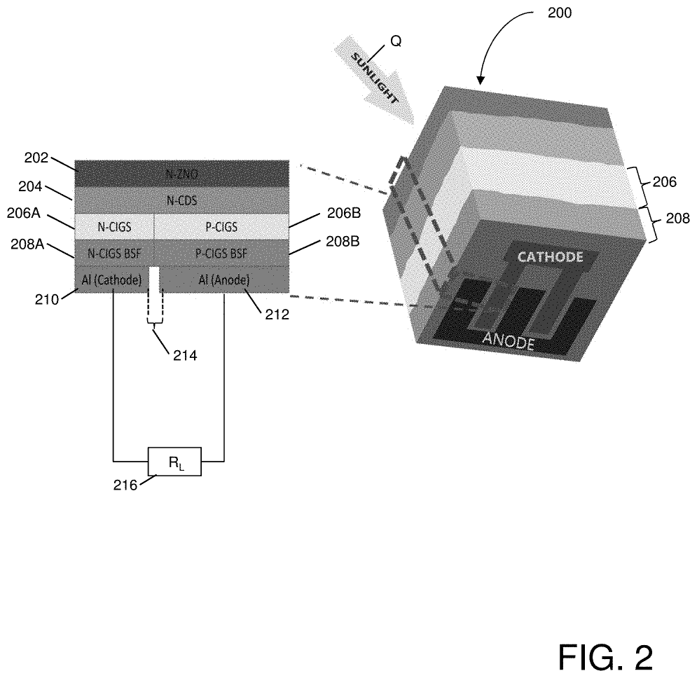

Embodiments in accordance with the invention provide a solar cell design having a single copper indium gallium di-selenide (CIGS) cell with a staggered back contacts (SBC). FIG. 2 illustrates a two-dimensional representation of a SBC CIGS cell 200 in accordance with one embodiment of the invention. In the present embodiment, SBC CIGS cell 200 has a top n-type zinc oxide (ZnO) window layer 202. ZnO has a bandgap (E_{G}) of 3.3 eV and is considered a transparent conducting oxide (TCO). Being transparent and conductive, ZnO allows photons to enter SBC CIGS cell 200 and interact with underlying layers as further described below.

Just below ZnO window layer 202 is an n-type cadmium sulfide (CdS) buffer layer 204. CdS has an E_{G} of 2.3 eV, and the purpose of CdS buffer layer 204 is to tunnel photons to an CIGS absorber layer 206 underlying CdS buffer layer 204. Directly below CdS buffer layer 204 is a CIGS absorber layer 206 divided into n-type CIGS section 206A and p-type CIGS section 206B. CIGS absorber layer 206 produces the majority of the carriers based on the number of photons that enter cell 200. CIGS absorber layer 206 is composed of two materials, CuInSe2 (CIS) and CuGaSe2 (CGS), both of which are direct bandgap semiconductors. Depending on the ratio of CIS to CGS, the bandgap can shift between 1.07-1.76 eV. Directly below CIGS absorber layer 206 is a CIGS back surface field (BSF) layer 208 divided into an n-type CIGS BSF section 208A and a p-type CIGS BSF section 208B. Beneath CIGS BSF layer 208 is an aluminum (Al) cathode contact 210 and an aluminum (Al) anode contact 212 formed in a staggered arrangement and separated by an insulator gap 214.

SBC CIGS cell 200 is lightweight, flexible and low cost. In one embodiment, a thin layer of n-type zinc oxide (ZnO) window layer 202 is utilized to collect carriers that are generated by impinging sunlight Q and then sends the carriers to cathode contact 210. N-type cadmium sulfide (CdS) buffer layer 204 funnels photons to CIGS absorber layer 206 and acts as the N side to the PN junction of SBC CIGS cell 200. CIGS absorber layer 206 is divided into an n-type CIGS section 206A and a p-type CIGS section 206B, with n-type CIGS section 206A funneling all the electrons and p-type CIGS section 206B funneling all the holes. CIGS BSF layer 208, having both n-type CIGS BSF section 208A and p-type CIGS BSF section 208B, acts as a back surface field (BSF) to increase the efficiency of SBC CIGS cell 200. Embodiments in accordance with the invention maintain the back surface reflector (BSR) by using the metal contacts, Al cathode contact 210 and Al anode contact 212 on the back of SBC CIGS cell 200 to recirculate photons and lower temperature. Layer properties (thickness, length, back contact material, etc.) can be optimized to improve overall conversion efficiency to 23%.

In operation, when a sunlight photon with energy greater than or equal to E_{G} of n-type ZnO window layer 202 enters cell 200, an electron hole pair (EHP) is generated. The EHP are primarily generated at the PN junction between n-type CdS buffer layer 204 and p-type CIGS layer 206B. With the help of the electric field within the depletion region of the PN junction, the EHP are separated. Due to n-type ZnO window layer 202 E_{G}, electrons are repelled away from the surface to prevent recombination. Now n-type CIGS layer 206A is funneling the electrons towards the metal contact, Al cathode contact 210 while the p-type CIGS layer 206B is funneling holes to its respective metal contact, Al anode contact 212. By adding n-type CIGS BSF sublayer 208A and p-type CIGS BSF sublayer 208B, an additional electric field is established and helps reduce recombination of EHP. When the two metal contacts, cathode contact 210 and anode contact 212, are connected to an electrical load, such as an external circuit 216 comprising load R_{L}, electrons travel from the cathode contact 210 to the anode contact 212, where the electrons recombine with holes. Air gap 214 is located between cathode contact 210 and anode contact 212 in order to prevent shorting the two terminals, cathode contact 210 and anode contact 212, of SBC CIGS cell 200.

To illustrate the increased efficiency of SBC CIGS cell 200, a simulation was successfully modeled of prior art top contact CIGS cell 100 made by the National Renewable Energy Laboratory (NREL). The actual NREL cell and simulated cell had approximately the same output parameters, supporting the assumption of an accurate model. The simulated cell characteristics are displayed in Table 1 below. Units are in microns (μm) for the length and thickness. The total area of the simulated prior art top contact CIGS cell is 0.994 cm².

TABLE 1
Basic characteristics for
simulation of a prior art
top contact CIGS cell.

| | Thickness (μm) | Doping (cm⁻³) |
|---|---|---|
| Al (cathode) | 0.5 | — |
| N-ZnO | 1.5 | 2 × 10¹⁸ |
| N-CdS | 0.15 | 2 × 10¹⁷ |
| P-CIGS | 2 | 2 × 10¹⁶ |
| Mo (anode) | 0.04 | — |

Unfortunately, the prior art top contact CIGS cell 100 top contact prevents photons from entering cell 100. In the simulated prior art top contact CIGS cell 100 model, 10% of the prior art top contact CIGS cell 100 was obscured by the top contact, i.e., shadowing.

In simulation of SBC CIGS cell 200, embodiments in accordance with the invention provide 18% more power output than a prior art CIGS cell 100 having a top contact. Table 2 shows the characteristics of one embodiment of a simulated of a SBC CIGS cell, such as SBC CIGS cell 200, in accordance with the invention. The units are in microns (μm). In the present embodiment, the total area of the SBC CIGS cell is 0.994 cm². Advantageously, embodiments in accordance with invention, maintain the BSR on the metal contacts, Al cathode contact 210 and Al anode contact 212, which improves efficiency and lowers temperature of cell 200. By adding an n-type CIGS layer 206, and CIGS BSF layers 208, electrons are now funneled to Al cathode contact 210, while holes continue to go towards Al anode contact 212.

TABLE 2
Characteristics for simulation of SBC CIGS CELL.

| | Thickness (μm) | Doping (cm⁻³) |
|---|---|---|
| N-ZnO | 0.40 | 2 × 10¹⁸ |
| N-CdS | 0.45 | 2 × 10¹⁷ |
| N-CIGS & P-CIGS | 11 | 2 × 10¹⁶ |
| N-CIGS & P-CIGS BSF | 6 | 1 × 10¹⁸ |
| Al (Anode) & Al (Cathode) | 0.40 | — |

As can be seen in FIG. 2, embodiments in accordance with the invention, as seen in SBC CIGS cell 200, no longer suffer from the 10% loss from the top contact seen in the prior art top contact CIGS cell 100. The staggered back design of SBC CIGS cell 200 removes the shadowing effect seen with the prior art top contact CIGS cell 100 design. This provides a simulated output power increase of 18% by SBC CIGS cell 200.

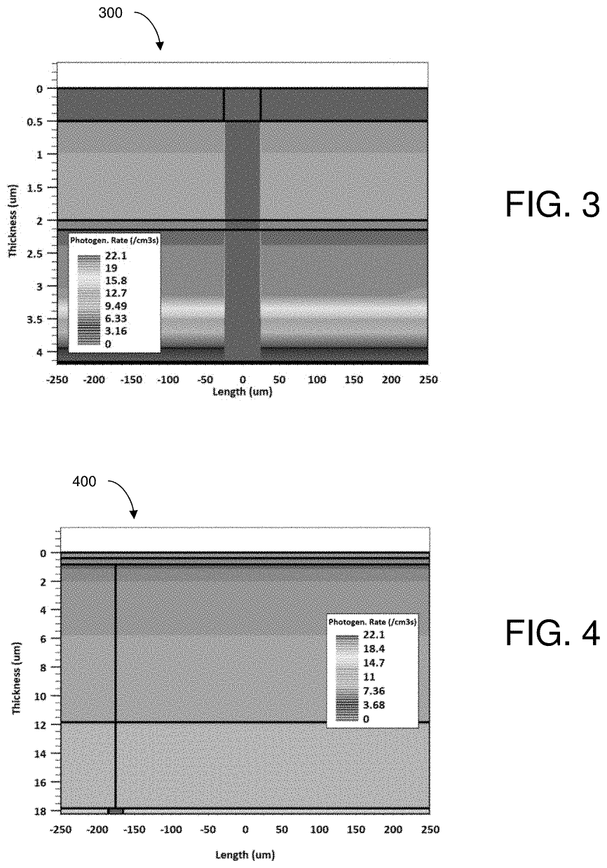

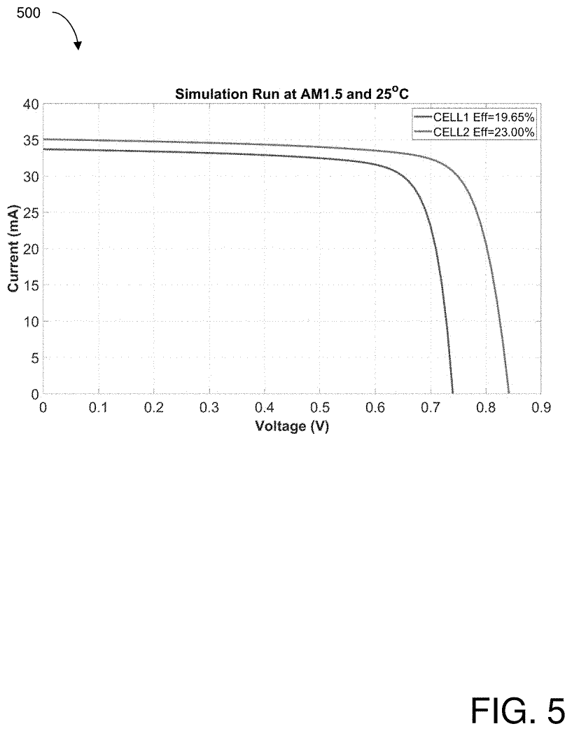

FIG. 3 illustrates a photon to electron interaction termed a photogeneration rate for a prior art top contact CIGS cell, such as cell 100. FIG. 4 illustrates a photogeneration rate for one embodiment of an SBC CIGS cell in accordance with the invention. In the prior art top contact CIGS cell 100, the top contact is in place, so photons are unable to interact with the cell down the center, which decreases the efficiency of the cell. As expected, most of the interaction happens at the top of cell 100 and works its way down. Differently, in the illustrated embodiment of the SBC CIGS cell 200, the top contact is moved to the bottom left corner. The CIGS layer thickness in SBC CIGS cell 200 is larger than the prior art top contact CIGS cell 100. There is a small insulator gap 214 in SBC CIGS cell 200 between the cathode contact 210 and anode contact 212 to prevent the two terminals from shorting. As expected, removing the top contact allows all the photons to interact with the SBC CIGS cell 200, which validates the efficiency improvement. The prior art top contact CIGS cell 100 design had an efficiency of 19.51% while the SBC CIGS cell 200 design in accordance with the invention had a 23.00% efficiency; which is a 18% improvement in power output. FIG. 5 shows the current versus voltage comparison between a prior art top contact CIGS cell 100 and one embodiment of the SBC CIGS cell 200 in accordance with the invention.

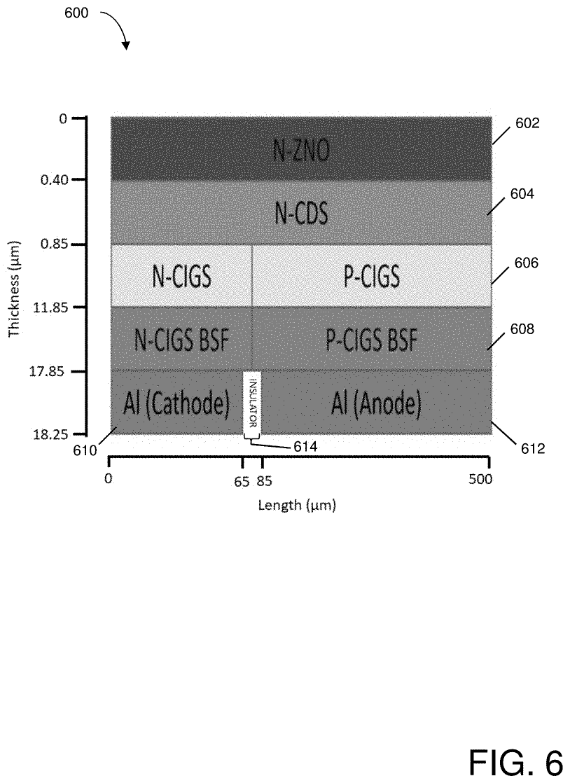

FIG. 6 shows example dimensions of one embodiment of a SBC CIGS cell 600 in accordance with the invention. Note the dimensions described may change slightly to optimize output parameters. Additionally, horizontal measurements represent one “slice” of SBC CIGS cell 600. In various embodiments, an actual SBC CIGS cell 600 can consist of many “slices” put together such that width of SBC CIGS cell 600 can vary based on design requirements.

As earlier described with reference to FIG. 2, SBC CIGS cell 600 has a top n-type zinc oxide (ZnO) window layer 602. Just below (ZnO) window layer 602 is an n-type cadmium sulfide (CdS) buffer layer 604. Directly below CdS buffer layer 604 is a CIGS absorber layer 606 divided into n-type CIGS section 606A and p-type CIGS section 606B. CIGS absorber layer 606 is composed of two materials, CuInSe2 (CIS) and CuGaSe2 (CGS), both of which are direct bandgap semiconductors. Directly below CIGS absorber layer 606 is a CIGS BSF layer 608 divided into an n-type CIGS BSF section 608A and a p-type CIGS BSF section 608B. Beneath BSF layer 608 is a cathode contact 610 and an anode contact 612 formed in a staggered arrangement in which cathode contact 610 is in contact with n-type CIGS BSF section 608A and anode contact 612 is in contact with p-type CIGS BSF section 608B. In various embodiments, cathode contact 610 and anode contact 612 can be made with Aluminum, Molybdenum or Copper. An insulator gap 614 prevents the two terminals from shorting cell 600. FIG. 6 displays one cell, however, multiple cells can be staggered side by side to achieve the higher performance. For example, increasing the area of the cell, increases the current. When multiple cells are connected in series, voltage is increased. In the present example embodiment, the area of the cell is 0.994 cm², with the width of the cell going into the paper.

This description provides exemplary embodiments of the present invention. The scope of the present invention is not limited by these exemplary embodiments. Numerous variations, whether explicitly provided for by the specification or implied by the specification or not, may be implemented by one of skill in the art in view of this disclosure.

It is to be understood that the above-described arrangements are only illustrative of the application of the principles of the present invention and it is not intended to be exhaustive or limit the invention to the precise form disclosed. Numerous modifications and alternative arrangements may be devised by those skilled in the art in light of the above teachings without departing from the spirit and scope of the present invention.

What is claimed is:

1. A staggered back contact (SBC) copper indium gallium di-selenide (CIGS) solar cell comprising:
a window layer comprising n-type zinc oxide (ZnO);
a buffer layer contacting the widow layer, the buffer layer comprising n-type cadmium sulfide (CdS);
an absorber layer contacting the buffer layer, the absorber layer comprising CIGS, and further divided into an n-type CIGS section and p-type CIGS section, further wherein the CIGS is composed of materials, CuInSe2 (CIS) and CuGaSe2 (CGS);
a back surface field (BSF) layer contacting the absorber layer, the BSF layer comprising CIGS, and further divided into an n-type CIGS BSF section and a p-type CIGS BSF section, wherein the n-type CIGS BSF section is in contact with the n-type CIGS section and the p-type CIGS BSF section is contact with the p-type CIGS section;
a conductive cathode contact contacting the n-type CIGS BSF layer; and,
a conductive anode contact contacting the p-type CIGS BSF layer;
wherein the cathode contact and the anode contact are arranged in a staggered arrangement and separated by an insulator gap.

2. The SBC CIGS solar cell of claim 1 wherein:
the window layer of ZnO has a doping concentration of 2×10¹⁸ cm⁻³;
the buffer layer of n-type CdS has a doping concentration of 2×10¹⁷ cm⁻³;
the absorber layer of CIGS comprises the n-type CIGS section having a doping concentration of 2×10¹⁶ cm⁻³ and the p-type CIGS section having a doping concentration of 2×10¹⁶ cm⁻³;
the BSF layer of CIGS comprises the n-type CIGS BSF section having a doping concentration of 1×10¹⁸ cm⁻³ and the p-type CIGS BSF section having a doping concentration of 1×10¹⁸ cm⁻³; and,
the cathode contact and the anode contact are each formed of Aluminum.

3. The SBC CIGS solar cell of claim 2 wherein:
the window layer of ZnO has a thickness of 0.40 μm;
the buffer layer of n-type CdS has a thickness of 0.45 μm;
the absorber layer of CIGS has a thickness of 11 μm;
the BSF layer of CIGS has a thickness of 6.0 μm;
the cathode contact has a thickness of 0.40 μm; and,
the anode contact has a thickness of 0.40 μm.

4. The SBC CIGS solar cell of claim 3 wherein the insulator gap between the cathode contact and the anode contact is 20 μm in length.

5. The SBC CIGS solar cell of claim 4 wherein the area of the cell is 0.994 cm².

6. The SBC CIGS solar cell of claim 1 wherein:
the window layer of ZnO has a doping concentration of 2×10¹⁸ cm⁻³;
the buffer layer of n-type CdS has a doping concentration of 2×10¹⁷ cm⁻³;
the absorber layer of CIGS comprises the n-type CIGS section having a doping concentration of 2×10¹⁶ cm⁻³ and the p-type CIGS section having a doping concentration of 2×10¹⁶ cm⁻³;
the BSF layer of CIGS comprises the n-type CIGS BSF section having a doping concentration of 1×10¹⁸ cm⁻³ and the p-type CIGS BSF section having a doping concentration of 1×10¹⁸ cm⁻³; and,
the cathode contact and the anode contact are each formed of a material selected from the group consisting of Aluminum, Molybdenum and Copper.

7. The SBC CIGS solar cell of claim 6 wherein:
the window layer of ZnO has a thickness of 0.40 μm;
the buffer layer of n-type CdS has a thickness of 0.45 μm;
the absorber layer of CIGS has a thickness of 11 μm;
the BSF layer of CIGS has a thickness of 6.0 μm;
the cathode contact has a thickness of 0.40 μm; and,
the anode contact has a thickness of 0.40 μm.

8. The SBC CIGS solar cell of claim 7 wherein the insulator gap between the cathode contact and the anode contact is 20 μm in length.

9. The SBC CIGS solar cell of claim 8 wherein the area of the cell is 0.994 cm².

10. The SBC CIGS solar cell of claim 8 further comprising:
an external circuit having a load, the external circuit connected at one end to the cathode contact and at the other end connected to the anode contact, such that when the cell is exposed to sunlight, electrons travel from the cathode contact to the anode contact.
